(19) United States
(12) Patent Application Publication
(10) Pub. No.: US 2002/0126026 A1
(43) Pub. Date: Sep. 12, 2002

(54) Information input system using bio feedback and method thereof

(75) Inventors: Sang-goog Lee, Incheon Metropolitan-City (KR); Jung-ho Kang, Gyeonggi-do (KR); Tae-sik Park, Gyeonggi-do (KR)

Correspondence Address: STAAS & HALSEY LLP, 700 11TH STREET, NW, SUITE 500, WASHINGTON, DC, 20001, US

(73) Assignee: Samsung Electronics Co., Ltd., Suwon-city (KR)

(21) Appl. No.: 09/976,007

(22) Filed: Oct. 15, 2001

(30) Foreign Application Priority Data
Mar. 9, 2001 (KR) 2001-12244

(51) Int. Cl. H03M 11/00; H03K 17/94

(52) U.S. Cl. 341/22

(57) ABSTRACT

An information input method of a computer system having a virtual keyboard includes detecting motion information of a user's hands and fingers, determining the locations of the user's hands and fingers by interpreting the detected motion information, displaying an input apparatus having a predetermined shape on the virtual keyboard of a screen based on the determined locations of the user's hands and fingers, and applying force to a finger corresponding to the location where information is input, if the input information is input by the displayed input apparatus.

### CROSS-REFERENCE TO RELATED APPLICATIONS

This application claims the benefit of Korean Application No. 2001-12244, filed Mar. 9, 2001, in the Korean Industrial Property Office, the disclosure of which is incorporated herein by reference.

### BACKGROUND OF THE INVENTION

1. Field of the Invention

The present invention relates to an information input system using bio feedback, and more particularly, to an information input system capable of obtaining a high recognition rate and high reliability using force feedback and bio feedback, and a method thereof.

2. Description of the Related Art

Generally, information processing apparatuses, such as computers, use a keyboard to input commands, characters, and numbers. That is, a conventional information input apparatus using a keyboard includes a key unit 110 having keys, a control unit 120 to detect pushed keys and to decode signals corresponding to the pushed keys, and a computer system 130 to display a character corresponding to the decoded signal, as shown in FIG. 1.

This conventional keyboard is generally connected to a desktop computer, and is not appropriate for a wearable or portable system. Therefore, to solve this problem, a virtual keyboard that is displayed on a screen is currently under development. The conventional virtual information input system includes a computer system 220 having a screen on which the virtual keyboard is displayed and a pointing apparatus 210 to select the buttons of the virtual keyboard as shown in FIG. 2. However, in the conventional virtual information input system, a user has to watch the virtual keyboard on the screen and use a mouse or a pen-type pointing apparatus 210 in order to input a character. Therefore, the speed of inputting the characters is very slow and, if the information input system is used for a long time, the user becomes very tired of inputting the characters.

### SUMMARY OF THE INVENTION

To solve the above and other problems, it is an object of the present invention to provide an information input method capable of improving inputting speed and accuracy, in which what a user desires to input is input by detecting the motion of a finger in space or on a plane.

It is a further object of the present invention to provide an information input method that improves a recognition rate and reliability by using force feedback and visual feedback.

It is another object of the present invention to provide an information input system that improves an accuracy recognition and reliability by applying the space-type information input method.

Additional objects and advantages of the invention will be set forth in part in the description which follows and, in part, will be obvious from the description, or may be learned by practice of the invention.

To accomplish the above and other objects, an information input method according to an embodiment of the present invention includes detecting motion information of a user's hands and fingers in space, determining locations of the user's hands and fingers by interpreting the detected motion information, and inputting information corresponding to the determined locations of the user's hands and fingers.

According to another embodiment of the present invention, an information input method of a computer system having a virtual keyboard, the information input method includes detecting motion information of human hands and fingers, determining locations of the user's hands and fingers by interpreting the detected motion information, displaying an input apparatus having a predetermined shape on the virtual keyboard of a screen by referring to the determined locations of the user's hands and fingers, and applying a force to a finger corresponding to the location where information is input, if the information is input by the displayed input apparatus.

According to a further embodiment of the present invention, an information input system includes sensors attached to predetermined parts of a user's hands and fingers to sense motions of the user's hands and fingers, an information input processing unit to convert the motion information of the user's hands and fingers into location information of the user's hands and fingers, to display an input apparatus having a predetermined shape on a virtual keyboard based on the converted location information of the user's hands and fingers, to determine a finger which inputs information, and to send an information input completion signal to the finger, a processor to convert the motion information detected by the sensors into data having a predetermined form, to send the converted data to the information input processing unit, and to receive an information input completion signal of a finger corresponding to the input information from the information input processing unit, and force generating units attached to predetermined parts of the user's fingers that apply a force to a corresponding finger if an information input completion signal sent by the processor is received.

According to a still further embodiment of the present invention, an information input system includes sensors attached to predetermined parts of a user's hands and fingers to sense motions of a user's hands and fingers, a processor to interpret locations of the user's hands and fingers based on the motions of the user's hands and fingers detected by the sensors, to send the interpreted locations to the computer, and to receive an information input completion signal from the computer, and force generating units attached to predetermined parts of the user's fingers and, if an information input completion signal generated by the processor is received, to apply a force to one of the user's fingers which input information.

### BRIEF DESCRIPTION OF THE DRAWINGS

The above and other objects and advantages of the present invention will become more apparent and more readily appreciated by describing in detail preferred embodiments thereof with reference to the accompanying drawings in which:

FIG. 1 is a block diagram of a conventional information input system using a conventional keyboard;

FIG. 2 is a block diagram of a conventional virtual information input system;

FIG. 3 is a perspective view of an information input system according to an embodiment of the present invention;

FIG. 4 is a diagram showing a finger part to which a sensor and a force generator are attached;

FIG. 5 is a block diagram of an embodiment of an information input system according to the present invention;

FIG. 6 is a block diagram of another embodiment of an information input system according to the present invention;

FIG. 7 is a detailed block diagram of an information input processing apparatus of the information input systems of FIGS. 5 and 6; and

FIG. 8 is a flowchart of an information input method according to an embodiment of the present invention.

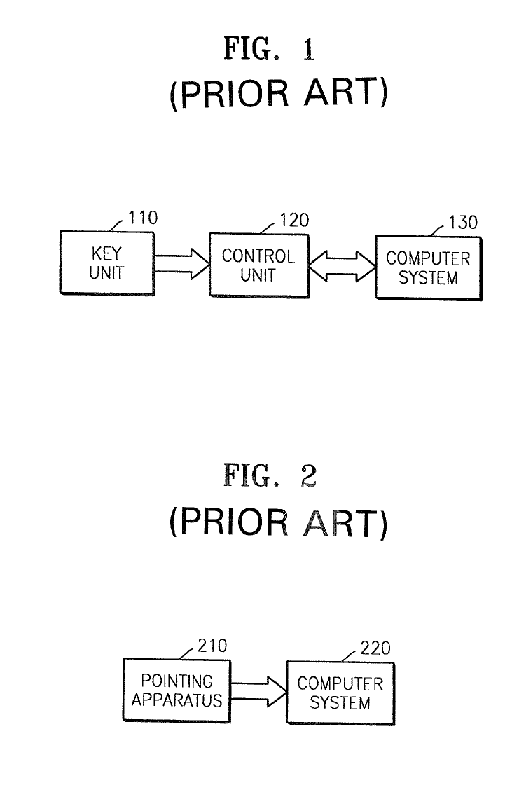

### DETAILED DESCRIPTION OF THE PREFERRED EMBODIMENTS

Reference will now be made in detail to the present preferred embodiments of the present invention, examples of which are illustrated in the accompanying drawings, wherein like reference numerals refer to the like elements throughout. The embodiments are described below in order to explain the present invention with reference to the figures.

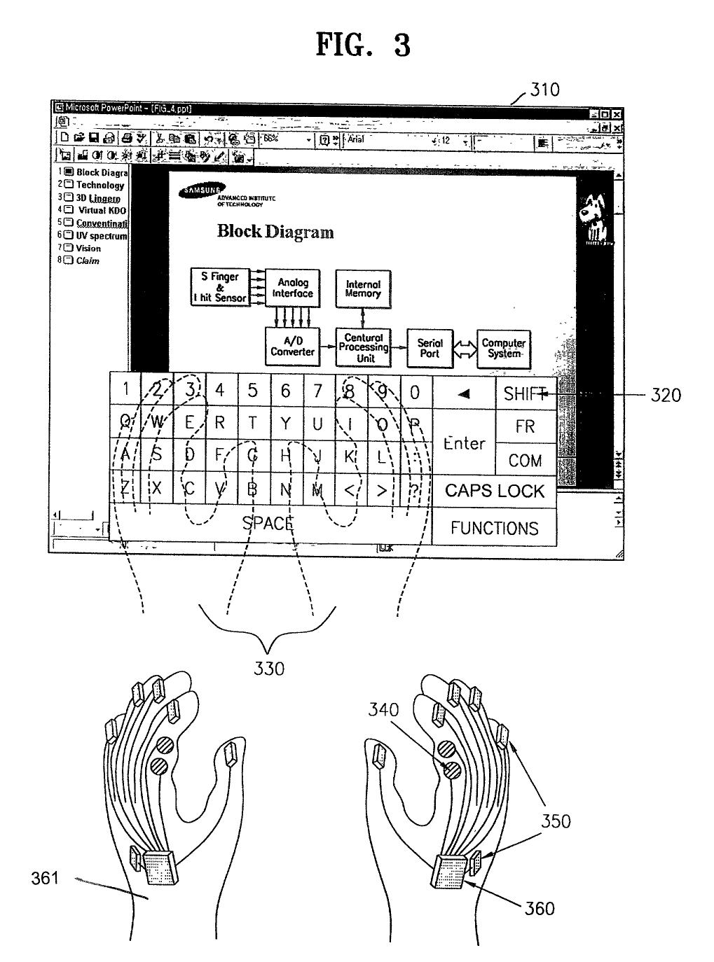

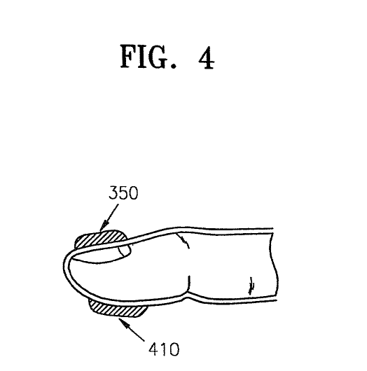

FIG. 3 is a perspective view of a space-type information input system according to an embodiment of the present invention and FIG. 4 is a diagram showing a finger part to which a sensor and a force generator are attached. Referring to FIGS. 3 and 4, the space-type information input system is divided into an information input apparatus 361 and an information input processing apparatus. First, the information input processing apparatus displays a virtual keyboard 320 for visual feedback. The virtual keyboard 320 is implemented by software encoded on a computer readable medium. The shape of an inputting apparatus 330 is displayed on the keyboard 320. It is preferable that the shape of the inputting apparatus 330 is a human hand. However, it is understood that the shape of the inputting apparatus 330 can take on other forms.

The information input apparatus 361, which has a glove shape, has sensors 350, attached to a user's fingers or to the back of the user's hand to sense the motion of the user's fingers, force generators 410, each for applying a force to a predetermined part of a finger, and a processor 360, which is attached either to the back of the user's hand or to the user's wrist and communicates information with the sensors 350 and force generators 410.

It is preferable that the sensors 350 are gyro sensors or IMEMS (inertial Micro-Electro Mechanical System) sensors. Preferably, the force generator 410 is a device that generates a force or a vibration. Also, it is preferable that the sensors 350 and the force generators 410 are attached to the user's fingernails and the bottom of the user's fingers, respectively. However, the sensors 350 and the force generators 410 may be other devices suitable for sensing and applying force and can also be attached to any parts of the user's fingers. Further, it is understood that the sensors 350 and the force generators 410 may be attached to other parts of the body, such as legs and other appendages, capable of motion to be detected for use in inputting information. It is also understood that the sensors 350 and the force generators 410 can be attached directly to the appendage, and that the information input apparatus 361 can be a frame or covering that covers only selective areas of the appendage to place the sensors 350 and the force generators 410 instead of a solid glove.

The information inputting apparatus also has switches 340, which are set to operate as function keys such as SHIFT, Ctrl, and Caps Lock. These switches 340 are operated by the user using fingers to depress the switches 340. However, the user may also set the switches 340 as arbitrary function keys. Preferably, the switches 340 are attached to a part between the first joint and the second joint of an index finger, but it is understood the switches 340 can be located on other fingers or on other areas of the body.

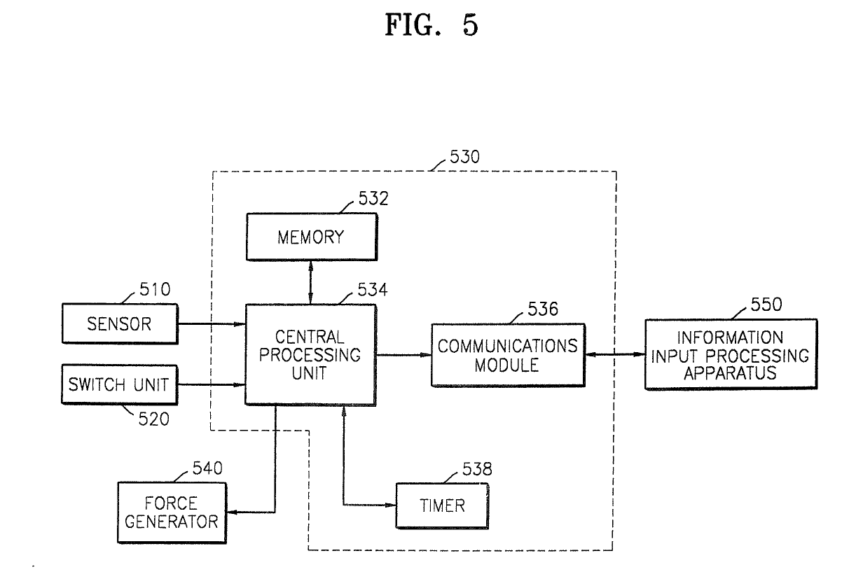

When used, an information input processing apparatus 550 shown in FIG. 5 detects motions of the user's hands and fingers, interprets the detected motions, and displays the motions of the user's hands on the virtual keyboard 320 so as to provide visual feedback of motions to the user. Also, the information input processing apparatus 550 detects a motion of fingers, inputs information on the corresponding location, and provides force feedback to the user so that the user can confirm the input. The hand shapes 330 displayed on the screen are overlaid on the virtual keyboard 320 based on the location information of the user' hands and fingers.

FIG. 5 is a block diagram of an embodiment of an information input system according to the present invention. Sensors 510 detect the motions of the user's hands and fingers and output acceleration information and/or angular velocity information in the form of a digital signal. A switch unit 520 generates function key signals that can be defined by a user, such as Shift, Ctrl, and Caps Lock. A processor 530 interprets the motion information of the user's hands and fingers, which are generated in the sensors 510, or a signal of a selected key generated by the switching unit 520, determines the locations of the user's fingers and hands, and then sends the determined location information to an information input processing apparatus 550 having a virtual keyboard 320. The processor 530 receives an information input completion signal from the information input processing apparatus 550 and applies force to corresponding user's hands and fingers using the force generator 540.

More specifically, the processor 530 has a central processing unit 534, a communications module 536, a memory 532, and a timer 538. The central processing unit 534 interprets the motion information of the user's hands and fingers, which is generated in the sensors 510, or a signal of a selected key generated by the switching unit 520, and determines the locations of the user's fingers and hands. The central processing unit 534 receives an information input completion signal from the information input processing apparatus 550 and sends the received signal to the force generators 540. The communications module 536 modulates the location information of the user's hands and fingers and/or the key information, which are processed in the central processing unit 534, sends the modulated information to the information input processing apparatus 550 by wire or wirelessly, receives an information input completion signal from the information input processing apparatus 550, and demodulates the received signal. The memory 532 stores a program for driving the central processing unit 534 to perform these processes. The timer 538 periodically informs the central processing unit 534 of the time so that the central processing unit 534 can process data in each predetermined cycle.

Based on the location information of the user's hands and fingers output from the processor 530, the information input processing apparatus 550 displays the shape of an inputting apparatus 330 on the virtual keyboard 320. It is preferable, but not necessary, that the shape of the inputting apparatus 330 is a human hand. If a motion of a user's finger to select a character is detected, information corresponding to the location of the finger is input, and, at the same time, an information input completion signal, containing the identifier (ID) of the finger which inputs the information, is generated.

The force generators 540 receives the information input completion signal generated in the central processing unit 534 and apply force to the part of the corresponding finger.

According to another embodiment of the present invention, the functions of the processor 530 and the information input processing apparatus 550 are set differently. Specifically, the processor 530 converts the detected motion information of the user's hands and fingers or key information into data, sends the converted data to the information input processing apparatus 550, and receives an information completion signal for a finger which inputs the information from the information input processing apparatus 550. The information input processing apparatus 550 interprets the motion information of the user's hands and fingers sent from the processor 530, determines the locations of the user's hands and fingers, and then performs the visual and force feedback functions.

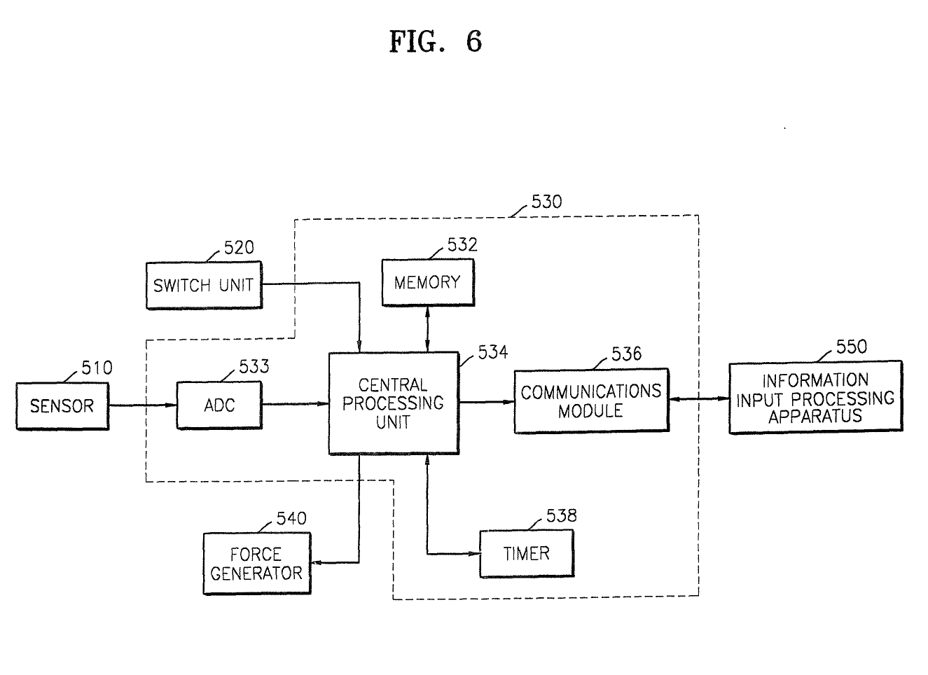

FIG. 6 is a block diagram of another embodiment of an information input system according to the present invention. Referring to FIG. 6, sensors 510 detect motions of the user's hands and fingers, output the detected motions as acceleration information or angular velocity information in the form of an analog signal. An analog-to-digital converter (ADC) converts the analog signal of the motion information generated in the sensors 510 into a digital signal. The other blocks in FIG. 6 have the same functions as explained in FIG. 5.

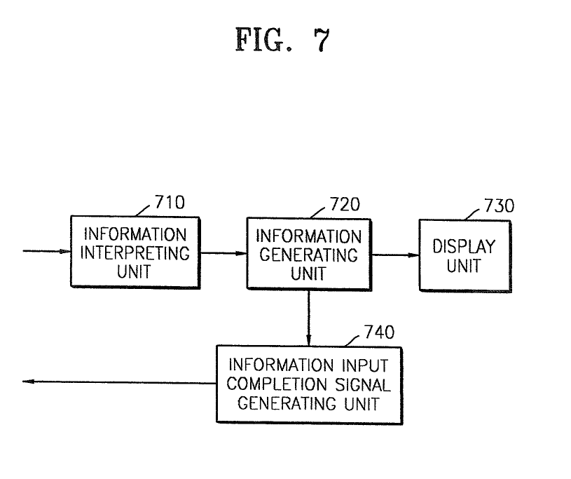

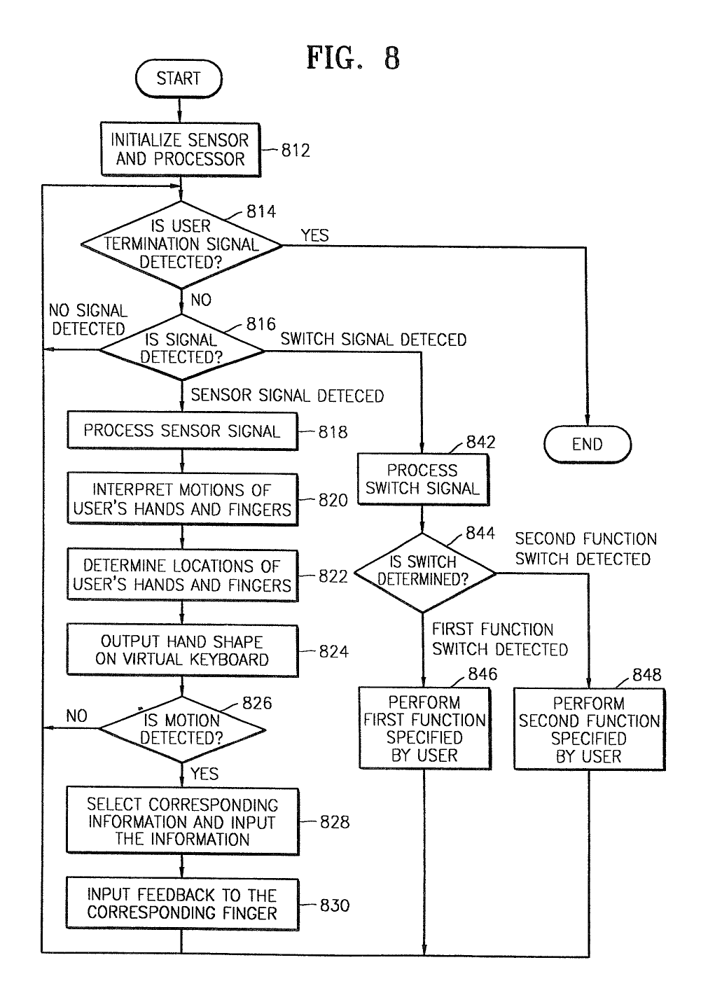

FIG. 7 is a detailed block diagram of an information input processing apparatus 550 of the information input systems of FIGS. 5 and 6. Referring to FIG. 7, an information interpreting unit 710 interprets the motion information input by the information input apparatus 361 and detects location information of the user's hands and fingers. Referring to the location information of the user's hands and fingers interpreted by the information interpreting unit 710, an information generating unit 720 generates information and a hand shape, which correspond to the location information, and at the same time, generates the location information of the finger which moved. An information input completion signal generating unit 740 receives the location information of the finger which moved (i.e., the location information generated by the information generating unit 720) and outputs an information input completion signal to the corresponding finger of the information input apparatus 361. A display unit 730 displays the information and hand shape, which are generated in the information generating unit 720.

FIG. 8 is a flowchart of an information input method according to the present invention. First, the sensors 510 and the processor 530 are initialized in operation 812. Then, it is determined whether or not a user termination signal is detected in operation 814. If the user termination signal is detected, the information processing is finished, and if the user termination signal is not detected, it is determined whether or not an input signal is detected in operation 816.

Therefore, after determining whether or not an input signal is detected, one of the following operations is performed depending on a type of the detected signal.

If a sensor signal is detected, the motion information of the user's hands and fingers generated by the sensors 510 is converted into data having a predetermined form which can be used by a computer in operation 818. Then, the motion information of the user's hands and fingers in the converted data form is interpreted in operation 820. The locations of the user's hands and fingers are determined by the interpreted motion information in operation 822. Then, based on the location information of the user's hands and fingers, a human hand shape is output on the virtual keyboard 330 in operation 824. Then, it is determined in operation 826 whether or not a motion corresponding to information selection on the virtual keyboard 320 by a predetermined finger is detected. If the click motion is detected, information corresponding to the location of the finger is input in operation 828. If the information is input, the information is displayed on the screen, and, at the same time, using the finger ID information, an information input completion signal is fed back to a force generator 540 attached to the user's finger which input the information.

If a switch signal is detected in operation 816, the function switch signal generated by the switching unit 520 is converted into data having a predetermined form which can be used by a computer in operation 842. At this time, it is determined by the function switch signal converted into the data whether the signal is a first function switch signal or a second function switch signal in operation 844. If the signal is the first function switch signal, the first function, which is defined by the user (for example, a control function (Ctrl)) is performed in operation 846. If the signal is the second function switch signal, the second function, which is defined by the user (for example, a shift function (Shift)) is performed in operation 848.

The above operations are repeated until a user termination signal is detected in operation 814.

So far, the embodiments of the present invention have been explained in the drawings and specification with reference to specific terminologies and shapes to explain the present invention. However, the present invention is not restricted to the above-described embodiments and many variations are possible within the spirit and scope of the present invention. For instance, the information input system according to the present invention is not only applied to a personal computer (PC), and electronic handheld devices, such as a personal digital assistant (PDA) and a mobile phone, but also applied to a wireless portable pointing apparatus, a wireless portable keyboard, an apparatus for recognizing hand motions and gestures, a virtual music playing apparatus, computer game systems, virtual environment exercise and training apparatuses, virtual reality data gloves, an apparatus for tracing mechanical shock and vibration, a monitoring apparatus, a suspension apparatus, and a robot motion information obtaining apparatus. Further, other types of input apparatuses could be simulated with or without hand shapes, and can also be simulated for non-human appendages as necessary.

According to the present invention as described above, a space-type information input using bio feedback enables a high recognition rate and a high reliability without a training process. Particularly, information is input quickly and accurately through bio feedback and information is input with high reliability by giving an input confirmation signal to a user through force feedback.

Although a few preferred embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An information input method comprising:
detecting motion information of hands and fingers in space;
determining locations of the hands and fingers by interpreting the detected motion information; and
inputting location information corresponding to the determined locations of the hands and fingers.

2. An information input method of a computer system having a virtual keyboard, the information input method comprising:
detecting motion information of hands and fingers;
determining locations of the hands and fingers by interpreting the detected motion information;
displaying a virtual input apparatus having a predetermined shape on a virtual keyboard of a screen by referring to the determined locations of the hands and fingers; and
applying a force to a finger corresponding to the location where information is input, if information is input using the displayed virtual input apparatus.

3. The information input method of claim 1, wherein said detecting the motion information comprises detecting the motion information using a sensor attached to a predetermined part of one of the fingers, where the sensor generates an acceleration signal in response to a movement of the one finger.

4. The information input method of claim 1, wherein one of the motion and location information is sent and received by wire or wirelessly.

5. The information input method of claim 2, wherein said determining the locations of the hands and fingers further comprises, if a signal of a switch to which a predetermined function is defined is detected, performing the predetermined function.

6. The information input method of claim 2, wherein the displayed virtual input apparatus has a predetermined shape that is displayed overlaying the virtual keyboard.

7. The information input method of claim 2, wherein said displaying the virtual input apparatus comprises displaying the motion of the virtual input apparatus having a predetermined shape on the screen in real time using the virtual keyboard and the detected motion information.

8. The information input method of claim 2, wherein said applying the force to the finger comprises applying the force using a force generator attached to a predetermined part of the finger that corresponds to the location where information is input.

9. An information input system comprising:
sensors attached to predetermined parts of hands and/or fingers to sense motions of the hands and/or fingers to produce motion information;
an information input processing unit to convert the motion information of the hands and/or fingers into location information of the hands and/or fingers, to display an input apparatus having a predetermined shape on a virtual keyboard based on the location information of the hands and/or fingers, to determine one of the fingers and hands which input information, and to send an information input completion signal to the one finger and/or hand;
a processor to convert the motion information detected by said sensors into data having a predetermined form, to send the converted data to said information input processing unit, and to receive the information input completion signal of the one finger and/or hand corresponding to the input information from said information input processing unit; and
a force generating units attached to predetermined parts of the fingers and/or hands, one of said force generating units to apply a force to the one finger and/or hand if an information input completion signal is received from said processor.

10. The information input system of claim 9, wherein said processor comprises:
an analog-to-digital converting unit to convert the detected analog motion information into a digital signal;
a central processing unit to convert the digital signal into data having a predetermined form, and to output the received information input completion signal to said one force generating unit; and
a communications module to modulate the converted digital signal, to send the modulated digital signal to said information input processing unit, and to receive the information input completion signal from said information input processing unit.

11. The information input system of claim 9, wherein said information input processing unit comprises:
an information interpreter to detect the location information of the hands and fingers by interpreting the motion information of the hands and fingers;
an information generator to generate an input apparatus having a predetermined shape based on the location information of the hands and/or fingers interpreted by the information interpreter, and to generate the location information of the one finger and/or hand which moved; and
an information input completion signal generator to output the information input completion signal to the corresponding one finger and/or hand based on the location information of the fingers generated by the information generator.

12. An information input system to input information to a computer, the information input system comprising:
sensors attached to predetermined parts of hands and/or fingers to sense a motion of the hands and/or fingers;
a processor to interpret a location of the hands and/or fingers based on the sensed motion of the hands and/or fingers detected by said sensors, to send the interpreted location to the computer, and to receive an information input completion signal from the computer; and
force generating units attached to other predetermined parts of the hands and/or fingers and, if the information input completion signal generated by said processor is received from said processor, to apply a force to one of the hands and/or fingers which input information.

13. The information input system of claim 9, wherein said force generating units comprise devices that generate vibration.

14. The information input system of claim 9, wherein said sensors comprise IMEMS (inertial Micro-Electro Mechanical System) sensors that sense information on the acceleration and angular velocity of the fingers and/or hands.

15. The information input system of claim 9, wherein said processor is attached to a back of the hands and/or to a wrist.

16. The information input system of claim 9, further comprising function keys attached additional predetermined parts of the hands and/or fingers to perform particular functions.

17. The information input system of claim 16, wherein one of said function key is attached to a predetermined part between joints of an index finger.

18. The information input system of claim 16, wherein one of the particular functions of said function keys is defined arbitrarily by a user.

19. The information input method of claim 2, wherein said detecting the motion information comprises detecting the motion information using a sensor attached to a predetermined part of one of the fingers, where one of the sensors generates an acceleration signal in response to a movement of the one finger.

20. The information input method of claim 2, wherein one of the motion and location information is sent and received by wire or wirelessly.

21. The information input system of claim 12, wherein said force generating units comprises devices to generate vibration.

22. The information input system of claim 12, wherein said sensors comprise IMEMS (inertial Micro-Electro Mechanical System) sensors to sense information on the acceleration and angular velocity of the fingers and/or hands.

23. The information input system of claim 12, wherein said processor is attached to a back of the hands and/or to a wrist.

24. The information input system of claim 12, further comprising function keys attached to additional predetermined parts of the hands and/or fingers to perform particular function.

25. The information input system of claim 24, wherein one of said function keys is attached to a predetermined part between joints of an index finger.

26. The information input system of claim 24, wherein one of the particular functions of said function keys is defined arbitrarily by a user.

27. An information input device attached to an appendage of a part of a body performing input to control a virtual input device generated by a computer, comprising:
a sensor to contact a first portion of the appendage to detect a motion of the first portion corresponding to the input to control the virtual input device, and to send the sensed motion to the computer; and
a force generating unit to contact a second portion of the appendage, to receive an input completion signal from the computer indicating that the input has controlled the virtual input device, and to apply a force to the second portion of the appendage based upon the received input completion signal.

28. The information input device of claim 27, further comprising a cover, wherein:
the appendage comprises a finger,
said sensor is attached to said cover to be placed on the finger, and
said force generating unit is attached to said cover to be placed on the finger.

29. The information input device of claim 27, wherein said sensor detects the motion of the finger relative to a motion of a hand to which the finger is attached.

30. The information input device of claim 27, further comprising a function key attached to said cover, said function key being configurable to send a message to perform a particular function on the virtual input device.

31. The information input device of claim 30, wherein the function being performed is one of SHIFT, Ctrl, and Caps Lock.

32. The information input device of claim 30, wherein the appendage includes an index finger, and the second portion is at or between first and second joints of the index finger such that said function key is attached to at or between the first and the second joints.

33. The information input device of claim 32, further comprising a cover, wherein said sensor is attached to said cover at the index finger and detects the motion of the index finger relative to a motion of a hand to which the index finger is attached, and said function key is attached to said cover at the first and second joints of the index finger.

34. The information input device of claim 32, further comprising a cover, wherein the appendage further comprises another finger, said sensor is attached to said cover at the another finger and detects the motion of the another finger relative to a motion of a hand to which the another finger is attached, and said function key is attached to said cover at the first and second joints of the index finger.

35. The information input device of claim 28, wherein said cover comprises a glove covering the finger and a hand to which the finger is attached.

36. An information input system, comprising:
a sensor attachable to an appendage to detect a relative motion of a part of the appendage relative to other parts of the appendage, and to send motion information according to the relative motion; and
an information input unit to generate a virtual input device, and to operate the virtual input device according to the motion information received from said sensor.

37. The information input system of claim 36, wherein said information input unit comprises:
an information interpreting unit to interpret a location of the appendage based upon the received motion information; and
an information generating unit to generate the virtual input device and a virtual appendage corresponding to the appendage, and to manipulate the virtual appendage relative to the virtual input device according to the interpreted location of the appendage.

38. The information input system of claim 36, further comprising a force generating unit that receives an information completion signal and applies a force to the part of the appendage based upon the received information completion signal, wherein said information input unit generates the information completion signal when the virtual input device is operated according to the motion information.

39. The information input system of claim 38, wherein said information input unit comprises:
an information interpreting unit to interpret a location of the appendage based upon the received motion information;
an information generating unit to generate the virtual input device and a virtual appendage corresponding to the appendage, and to manipulate the virtual appendage relative to the virtual input device according to the interpreted location of the appendage; and
an information input completion generating unit to generate the information completion signal when the virtual appendage is manipulated to complete an input into the virtual input device.

40. The information input system of claim 39, wherein the appendage is a finger of a hand, the virtual appendage is a virtual finger, and the virtual input device is a virtual keyboard which is operated by the virtual finger in accordance with the motion information.

41. A computer readable medium encoded with processing instructions for implementing an information input method performed by a computer to be connected to a sensor attached to a first portion of an appendage, the method comprising:
receiving motion information from the sensor, the motion information being generated in accordance with a motion of the first portion of the appendage relative to a second portion of the appendage;
interpreting the received motion information to determine a location of the first portion of the appendage;
generating a virtual input device and a virtual appendage; and
moving the virtual appendage in accordance with the determined location of the first portion of the appendage to operate the virtual input device.

42. The computer readable medium of claim 41, further comprising displaying the virtual input device and the virtual appendage on a display.

43. The computer readable medium of claim 42, further comprising:
determining when the moved virtual appendage has operated the virtual input device; and
generating an input completion signal to be sent to a force generating unit to apply a force to the appendage.

44. The computer readable medium of claim 43, wherein:
the appendage comprises a hand and the first portion of the appendage comprises a finger of the hand,
said generating the virtual input device comprises generating a virtual keyboard and said generating the virtual appendage comprises generating a virtual finger corresponding to the finger of the hand, and
said moving the virtual appendage comprises moving the virtual finger to depress an element of the virtual keyboard.

45. The computer readable medium of claim 44, wherein said generating the input completion signal comprises generating the input completion signal to apply the force to the finger of the hand.
